(19) United States
(12) Patent Application Publication
(10) Pub. No.: US 2025/0323657 A1
(43) Pub. Date: Oct. 16, 2025

(54) DEVICE AND METHOD FOR ANALOG TO DIGITAL CONVERSION

(71) Applicant: Dolphin Semiconductor, MEYLAN (FR)

(72) Inventors: Toni SAADE, MEYLAN (FR); Damien D'ESPERONNAT, MEYLAN (FR); Paul GILETTI, MEYLAN (FR)

(21) Appl. No.: 19/098,614

(22) Filed: Apr. 2, 2025

(30) Foreign Application Priority Data
Apr. 10, 2024 (FR) 2403712

(51) Int. Cl. H03M 1/36; H03M 3/00

(52) U.S. Cl. CPC H03M 1/361; H03M 3/458

(57) ABSTRACT

The present disclosure relates to an analog-to-digital converter, comprising: one or more comparators, each signal with a variable configured to compare an analog reference level specific to the comparator; a controller coupled to an output of the one or more comparators and configured to generate a control signal indicating the reference level of each comparator as a function of an output signal from each of the one or more comparators and configured to generate a digital output signal based on the output signal from each of the one or more comparators.

### TECHNICAL FIELD

The present disclosure generally relates to devices and methods for analog-to-digital conversion.

### BACKGROUND ART

An analog signal can be converted into a digital signal by analog-to-digital converters comprising, for example, a set of comparators. Each comparator then compares the analog signal with a fixed reference level specific to each comparator, and the analog signal level is estimated from the set of output signals of the comparators. The number of comparators in such a converter increases linearly with the number of reference levels.

The greater the number of comparators included in the converter, the greater its power consumption and footprint. There is therefore a need for an analog-to-digital converter with a relatively low power consumption and/or footprint.

### SUMMARY OF INVENTION

One embodiment provides an analog-to-digital converter, comprising:
one or more comparators, each configured to compare an analog signal with a variable reference level specific to the comparator; and
a controller coupled to an output of the one or more comparators, and configured to generate a control signal indicating the reference level of each comparator as a function of an output signal of each of the one or more comparators, and configured to generate a digital output signal based on the output signal of each of the one or more comparators.

According to one embodiment, the analog signal is oversampled.

According to one embodiment, the reference level of each comparator is selected from a plurality of discrete voltage levels.

According to one embodiment, the number of comparators is greater than or equal to two, and the reference levels of the comparators are selected to be consecutive levels from the plurality of discrete voltage levels.

According to one embodiment, the analog-to-digital converter further comprises a comparator reference level generator, comprising a voltage divider formed by a plurality of series-connected resistors or diodes.

According to one embodiment, the reference level generator comprises a multiplexer configured to select reference levels based on the control signal.

According to one embodiment, the analog-to-digital converter further comprises at least one digital-to-analog converter coupled to an output of the controller and configured to convert the control signal into one or more reference voltage levels supplied to the one or more comparators or supplied to one or more voltage supply terminals of the reference level generator.

According to one embodiment, the voltage difference between two consecutive reference levels and the sampling frequency are chosen so that the variation in amplitude of the analog signal between two consecutive samples does not exceed twice said voltage difference.

Another embodiment provides a Delta-Sigma analog-to-digital converter, comprising the analog-to-digital converter described above.

Another embodiment provides a method for analog-to-digital conversion, comprising:
comparing, by one or more comparators of an analog-to-digital converter, an analog signal with a variable reference level specific to the comparator;
generating a control signal, by a controller coupled to an output of the one or more comparators, indicating the reference level of each comparator as a function of an output signal of each of the one or more comparators; and
generating a digital output signal, by the controller, on based on the output signal from each of the one or more comparators.

According to one embodiment, the analog signal is oversampled.

According to one embodiment, the method further comprises selecting the reference level of each comparator from a plurality of discrete voltage levels.

According to one embodiment, the number of comparators is greater than or equal to two, and the reference levels of the comparators are selected to be consecutive levels from the plurality of discrete voltage levels.

According to one embodiment, the method further comprises converting the control signal, by at least one digital-to-analog converter coupled to an output of the controller, into a voltage level supplied to a voltage divider, formed by a plurality of series-connected resistors or diodes, included in a reference level generator.

According to one embodiment, the method further comprises selecting reference levels based on the control signal, by a multiplexer coupled to an output of a reference level generator comprising a voltage divider formed by a plurality of series-connected resistors or diodes.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates an example of a Flash analog-to-digital converter;

FIG. 2 is a graphic of an analog signal voltage and a corresponding voltage of a digital signal after conversion by an analog-to-digital converter;

FIG. 3A schematically illustrates an analog-to-digital converter according to one embodiment of the present description;

FIG. 3B schematically illustrates a reference level generator according to one embodiment of the present description;

FIG. 3C is a flowchart of an example of an algorithm for choosing reference levels to be selected for the analog-to-digital converter shown in FIG. 3A;

FIG. 4 schematically illustrates an example of the evolution of the voltage of signals present in the device shown in FIG. 3A over time;

FIG. 5 illustrates, in flowchart form, a method for analog signal conversion according to one embodiment of the present description;

FIG. 6 graphically illustrates an example of voltage evolution of signals present in the device shown in FIG. 3A over time, in the case where the device shown in FIG. 3A comprises only one comparator; and

FIG. 7 schematically illustrates a sigma-delta-type analog-to-digital converter.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following description, an oversampled signal is defined as a signal the sampling frequency of which is higher than the Nyquist frequency.

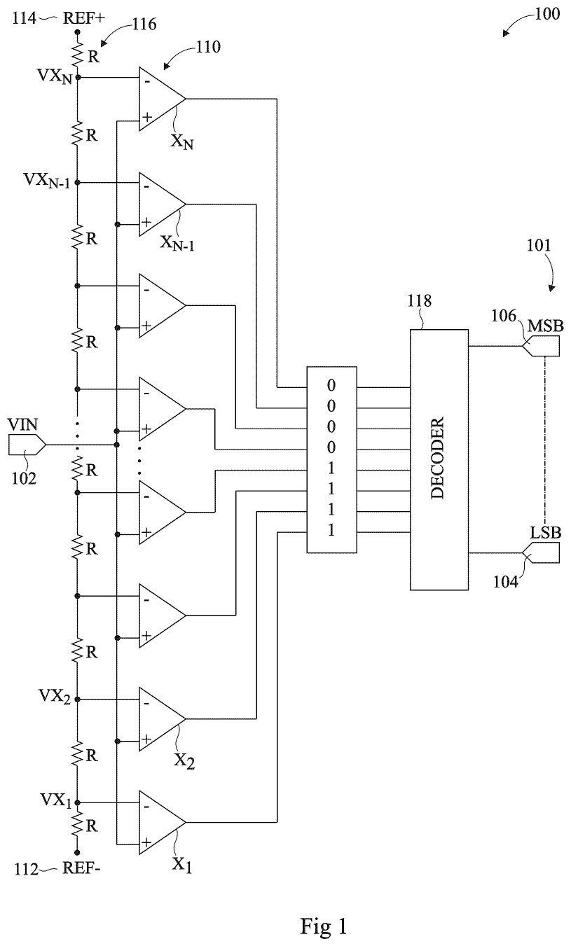

FIG. 1 illustrates an example of a Flash analog-to-digital converter 100, sometimes also referred to as a parallel analog-to-digital converter.

Device 100 takes as input an analog signal 102 (“VIN”) and is configured to convert it into a digital signal 101 consisting of N bits ranging from a least significant bit (LSB) 104 to a most significant bit (MSB) 106. Converter 100 comprises N comparators X₁, X₂, . . . , X_{N-1}, X_{N} collectively referenced 110 each taking the analog signal 102 at their positive input and a reference voltage at their negative input. According to another embodiment, not illustrated in FIG. 1, the comparators take each the analog signal 102 at their negative input and a reference voltage at their positive input. The reference voltages are set by a voltage divider 116 comprising first 112 and second 114 voltage supply terminals and a set of resistors connected in series between the two terminals. The first voltage terminal 112 is at a first voltage REF-, for example coupled to a ground rail, and the second voltage terminal 114 is at a second voltage REF+, for example coupled to a supply voltage rail. The first voltage REF-is lower than the second voltage REF+. The resistors of the voltage divider 116 have the same resistance value “R”, for example. A set of N regularly spaced, increasing voltage values Vx₁, Vx₂, . . . . Vx_{(N-1)}, Vx_{N} is thus obtained at the nodes coupling the resistors to each other. The voltages Vx₁, Vx₂, . . . , Vx_{(N-1)}, Vx_{N} are the reference voltages, also known as reference levels, and are coupled to the comparators X₁, X₂, . . . , X_{N-1}, X_{N} respectively. Each of the comparators in assembly 110 outputs a digital signal having, for example, a high voltage (“1”) if input signal 102 is greater than the reference signal of the comparator, and a low voltage (“0”) if input signal 102 is less than the reference signal of the comparator. The outputs of the comparators 110 are coupled to a decoder 118 (“DECODER”) which outputs the digital signal 101 in the form of bits ranging from the least significant bit 104 to the most significant bit 106.

An analog-to-digital converter such as device 100, comprising N comparators, categorizes the values taken by analog signal 102 among N+1 voltage levels. Increasing the number of levels, and therefore the accuracy and/or voltage range of the converter, is accompanied by a linear increase in the number of comparators, and therefore in the area surface and power consumption required.

Although the voltage divider 116 shown in FIG. 1 is implemented using series resistors, in another embodiment diodes are used.

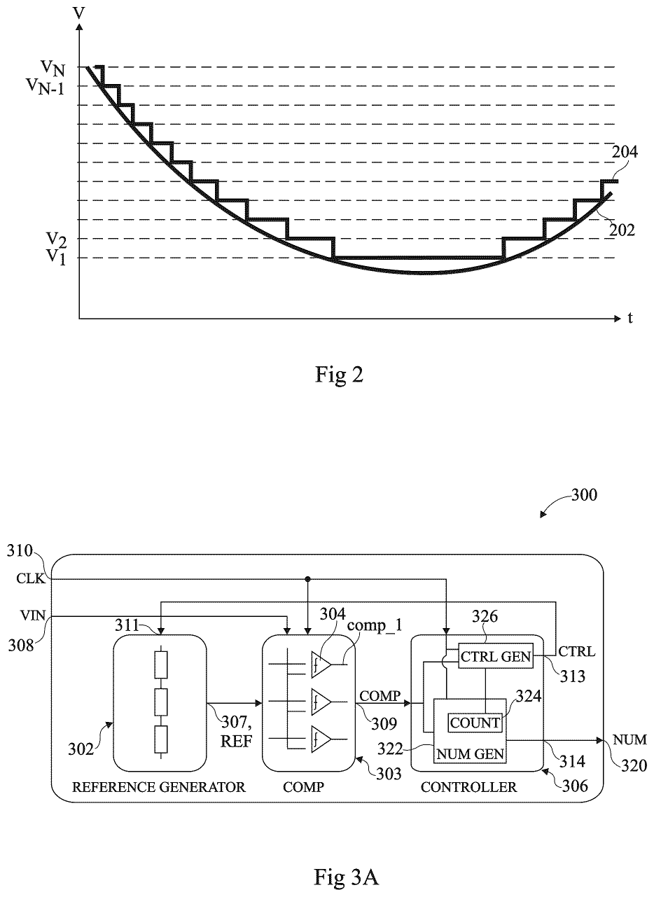

FIG. 2 is a graph of a voltage (“V”) of an analog signal 202 and a voltage of a corresponding digital signal 204 after conversion by an analog-to-digital converter.

Analog signal 202 varies continuously over time (“t”). The digital signal 204 can only assume a finite number of discrete values V₁, V₂, . . . V_{N-1}, V_{N} corresponding to the number of converter levels.

The value of the analog signal 202 is sampled, for example, and the samples converted into digital values at regular time intervals, for example governed by a clock signal.

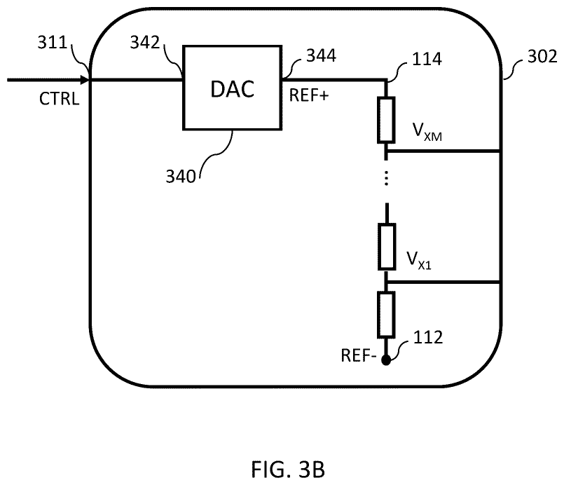

FIG. 3A schematically illustrates an analog-to-digital converter 300 according to one embodiment.

The analog-to-digital converter 300, for example, is part of a Sigma-Delta-type converter.

The analog-to-digital converter 300 comprises a first input 308 configured to receive an analog signal VIN, a second input 310 configured to receive a clock signal CLK, and an output 320 configured to provide a digital output signal NUM.

The analog-to-digital converter 300 comprises three modules: a reference level generator 302 (“REFERENCE GENERATOR”), a comparator set 303 (“COMP”) and a controller 306 (“CONTROLLER”).

The reference level generator 302 is, for example, capable of generating any voltage from a set of N reference voltage levels, N being equal to at least two and being selected, for example, as a function of the sampling frequency of the analog signal, the amplitude of the analog signal variations, the number of comparators 304, etc. In some cases, reference level generator 302 is implemented by a voltage divider comprising, for example, a set of N+1 resistors connected in series between two voltage terminals. In some cases, the generator 302 is implemented by the voltage divider 116 of the device 100 shown in FIG. 1. The reference level generator 302 comprises, for example, N voltage nodes, each intermediate to two adjacent resistors, corresponding to N distinct and increasing voltage values, for example the voltages Vx₁, Vx₂, . . . , Vx_{(N-1)}, Vx_{N} shown in FIG. 1. The reference level generator 302 is configured, for example, to generate at M outputs 307 a number M, between 2 and N, of reference levels REF. The number M corresponds to the number of comparators 304 in the comparator set 303. In addition, the M generated reference levels REF correspond to M consecutive voltage values from the N values Vx₁, Vx₂, . . . , Vx_{(N-1)}, Vx_{N}. The reference level generator 302 has, for example, an input 311 coupled to an output 313 of the controller 306 and takes, for example, as input a control signal CTRL generated by the controller 306. The control signal CTRL indicates the M reference levels REF to be transmitted.

According to one embodiment, the reference level generator 302 comprises M multiplexers, not illustrated in FIG. 3A, each multiplexer taking, for example, as input all or some of the N voltages Vx₁, Vx₂, . . . Vx_{(N-1)}, Vx_{N}, and being controlled by the control signal CTRL to transmit each one of the M reference levels REF to the M outputs 307.

According to another embodiment, illustrated in FIG. 3B, the reference level generator 302 comprises a number of resistors less than N+1, for example equal to M+1.

FIG. 3B schematically illustrates the reference level generator 302 according to this embodiment of the present description.

The resistors are connected in series between the supply voltage levels REF− and REF+ (see FIG. 1), and the voltage level REF+ is variable and controlled by the control signal CTRL. At least one digital-to-analog converter 340 is then present in the reference level generator 302. The digital-to-analog converter 340 (“DAC”) is configured to convert the control signal CTRL, received at an input 342 coupled to input 311, into an analog signal, for example the analog signal REF+, at an output 344 coupled to the voltage terminal 114 shown in FIG. 1. The voltage level REF− is, for example, fixed and corresponds, for example, to the voltage of the ground rail, not illustrated in FIG. 3B. According to another embodiment, the signals REF− and REF+ are both variable and supplied by two digital-to-analog converters, each controlled by the control signal CTRL.

Referring back to FIG. 3A, and according to another embodiment, not illustrated in FIG. 3A, the reference level generator 302 comprises one or more digital-to-analog converters coupled to an output of the controller 306, and configured to convert the digital control signal CTRL into M analog reference voltage levels REF transmitted to the M outputs 307.

The comparator set 303 of the analog-to-digital converter 300 comprises M comparators 304. Each of the comparators 304 has a first input connected to the analog signal VIN, and a second input connected to one of the M outputs 307 of the reference voltage generator 302. Each of the M comparators 304 compares the analog signal VIN with a corresponding one of the M consecutive reference levels REF. For example, the analog signal VIN is sampled, and the samples compared with the M reference levels REF, at regular intervals at a frequency given by the clock signal CLK. The sampling frequency defined by the clock signal CLK is, for example, high enough for the analog signal VIN to be oversampled. For example, the sampling frequency is between 1 and 10 MHZ, for example between 5 and 7 MHz, for a bandwidth of the signal VIN of between 1 and 50 kHz, for example between 15 and 25 kHz.

According to some embodiments, the sampling frequency is at the Nyquist frequency, and the analog signal VIN has a low dynamic range, i.e. small variations in amplitude.

According to other embodiments, the analog signal VIN comprises a signal with a low frequency, and having a high dynamic range superimposed on a signal with a high frequency and low dynamic range.

Each of the M comparators 304 outputs, based on the comparison, a digital signal comp_1, . . . , comp M having, for example, a high voltage (“1”) if the analog signal VIN is greater than the reference signal of the corresponding comparator, and, for example, a low voltage (“0”) if the analog signal VIN is less than the reference signal of the corresponding comparator. All M digital signals COMP are transmitted via M outputs 309 of the comparator set 303.

In some cases, the voltage difference between 2 consecutive reference levels REF and the sampling frequency are selected so that the variation in amplitude of the analog signal VIN between two consecutive samples does not exceed twice said voltage difference.

The generation of the clock signal CLK, for example by an external circuit not illustrated, is known to those skilled in the art and will not be described in detail.

The controller 306 comprises M inputs coupled to the M outputs 309 of the module 303, these M inputs being configured to receive all digital signals COMP. The controller 306 also comprises, for example, an input configured to receive the clock signal CLK. The controller 306 is configured to generate the digital output signal NUM at an output 314 of the controller 306, the output 314 being coupled to the output 320 of the device 300. The digital output signal NUM corresponds to the conversion of the analog signal VIN by the device 300, and is used, for example, by other external digital circuits not illustrated. The controller 306 is also configured to generate the control signal CTRL at output 313.

The controller 306 comprises, for example, a circuit 322 (“NUM GEN”) comprising an input configured to receive the signal CLK and M inputs coupled to the M outputs 309 of the module 303 in order to receive the digital signals COMP. The circuit NUM GEN is configured to generate the digital output signal NUM. The circuit NUM GEN comprises, for example, a counter 324 (“COUNT”) configured to store a level representing the reference levels to be applied to the comparators. For example, the counter COUNT stores the rank of the lowest reference level REF used in the last comparison. According to one embodiment, the circuit NUM GEN is configured to analyze the set of signals COMP and, using the value recorded by the counter during the previous comparison, to deduce the level of the sample being compared. For example, the circuit NUM GEN is configured to update the counter value and generate the signal NUM at output 314.

For example, the controller 306 also comprises a circuit 326 (“CTRL GEN”) comprising an input configured to receive the signal CLK and M inputs coupled to the M outputs 309 in order to receive the digital signals COMP. The circuit CTRL GEN is configured to generate the control signal CTRL at an output coupled to the output 313 of controller 306. According to one embodiment, the circuit CTRL GEN is configured to read the values of signals COMP corresponding to the maximum and minimum reference values REF to generate the control signal CTRL indicating a variation in the reference signals REF. According to another embodiment, the circuit CTRL GEN also comprises an input coupled to an output of the counter COUNT of the circuit NUM GEN, and is configured, for example, to generate the control signal CTRL indicating the reference values REF to be applied for the next comparison.

Generating the signals NUM and CTRL by the circuits NUM GEN and CTRL GEN as well as incrementing the counter are clocked by the signal CLK.

According to another embodiment, the controller 306 has no input coupled to the clock signal CLK. The signals CTRL and NUM are, for example, asynchronous and generated by a variation in or reading of the signal COMP.

According to one embodiment, device 300 is configured to activate a variable number of comparators 304 over time and to generate, via reference level generator 302, the number of reference values REF corresponding to the number of activated comparators. The other comparators are deactivated, for example. The number of active comparators 304 varies, for example, to follow the rate of variation in amplitude of the analog signal VIN. Concurrent use of a large number of comparators 304 enables large variations in amplitude of the analog signal VIN over time to be tracked, while the use of a small number of comparators 304 enables the power consumption of the device 300 to be temporarily reduced. The controller 306 is configured, for example, to perform selecting the number of comparators to be used for each comparison, for example as a function of the speed of level variations recorded over the previous few comparisons, for example stored in a memory in the controller 306. For example, the speed information is indicated by the variation in the digital value NUM at the output of the device 300 and/or by increment and/or decrement values of the value of the counter COUNT.

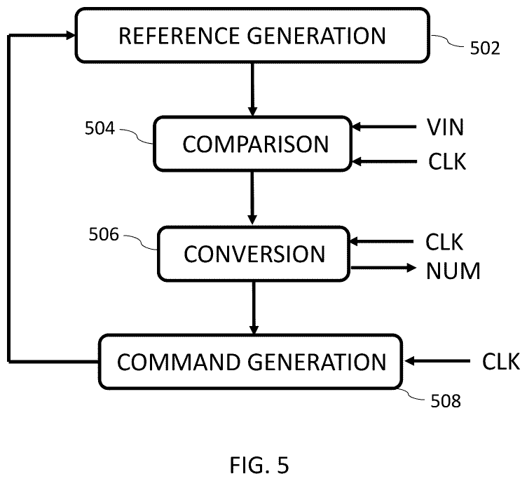

According to another embodiment, device 300 comprises a single comparator 304 and N possible reference voltages REF. The number of comparators no longer allows the value of the analog signal VIN over time to be framed. According to an algorithm detailed in FIG. 6, device 300 is configured to compare the value of consecutive samples of analog signal VIN with a reference value that evolves as a function of the result of the previous comparison. The level of the signal VIN is considered reached when the single reference value oscillates around the value of the analog signal VIN. In this operating mode, the analog signal VIN has, for example, slow variations in amplitude relative to the sampling frequency.

FIG. 3C is a flowchart of an example algorithm for selecting the M reference levels REF to be selected from the analog-to-digital converter 300 shown in FIG. 3A.

In the example shown in FIG. 3C, the converter 300 comprises 17 resistors, and is capable of generating 16 reference voltage values REF. The converter 300 also includes 3 comparators.

FIG. 3C illustrates the states that the controller 306 can assume, corresponding to the level values (“Level”) stored by the counter COUNT.

During an initialization step 350 (“NRST==0”), for example when the device 300 is switched on, the counter COUNT is initialized to the 7^{th} level (“Level=7”) and the 3 reference levels REF take on the 7^{th}, 8^{th}, and 9^{th} reference values. The analog signal VIN is compared with the 3 reference levels REF by the three comparators, a first comparator comparing the signal VIN with the lowest reference level (e.g. the 7^{th} value when the counter is at the 7^{th} level), a second comparator comparing the signal VIN with the middle reference level (the 8th value when the counter is at the 7^{th} level), and a third comparator comparing the signal VIN to the highest reference level (the 9^{th} value when the counter is at the 7^{th} level). The three comparators 304 generate three digital signals comp_1, comp_2, and comp_3 characteristic of the comparison (“out[7]=comp_1”, “out[8]=comp_2” and “out[9]=comp_3”).

In the example shown in FIG. 3C, the controller 306 analyzes the digital signals COMP from the first comparator, with the lowest reference value, and from the third comparator, with the highest reference value.

If the third comparator has a high output voltage (“comp_3==1”), in a step 354, the controller 306 is configured to increment the counter COUNT and to generate the control signal CTRL instructing the generator 302 to switch to the higher reference levels. The controller 306 thus switches to the state corresponding to level 8 (“Level=8”), and the 3 reference levels REF take on the 8^{th}, 9^{th}, and 10^{th} reference values.

In the state corresponding to level 8, the analog signal VIN is compared with the 3 reference levels REF and the three comparators 304 generate three digital signals comp_1, comp_2, and comp_3 characteristic of the comparison (“out[8]=comp_1”, “out[9]=comp_2” and “out[10]=comp_3”). If the third comparator still has a high output voltage (“comp_3==1”), controller 306 repeats step 354 in order to switch to the higher state (not illustrated in FIG. 3C), and is configured to generate the control signal CTRL instructing generator 302 to switch to the higher reference levels.

Step 354 is repeated as long as the third comparator has a high output voltage, until the maximum state is reached, corresponding to level 14 (“Level=14”) in this example. The 3 reference levels REF then take on the 14^{th}, 15^{th}, and 16^{th} reference values. The analog signal VIN is compared with the 3 reference levels REF. The three comparators 304 generate three digital signals comp_1, comp_2, and comp_3 characteristic the of comparison (“out=comp_1”,“out[15]=comp_2” and “out=comp_3”). If the third comparator still has a high output voltage (“comp_3==1”), controller 306, in a step 358, is configured to generate the control signal CTRL instructing generator 302 to remain at maximum level.

If, when the controller is in the state corresponding to level 8, the first comparator has a low output voltage (“comp_1==0”), the controller 306, in a step 362, is configured to decrement the counter COUNT, and to generate the control signal CTRL instructing the generator 302 to switch to the lower reference levels. The controller 306 thus switches to the state corresponding to level 7 (“Level=7”).

In the state corresponding to level 7, if the first comparator comp_1 still has a low output voltage (“comp_1==0”), the controller 306 repeats step 362 in order to switch to the lower state (not illustrated in FIG. 3C), and is configured to generate the control signal CTRL instructing the generator 302 to switch to the lower reference levels.

Step 362 is repeated as long as the first comparator has a low output voltage, until the minimum state is reached, corresponding to level 1 (“Level=1”) in this example. The 3 reference levels REF then take on the 1^{st}, 2^{nd}, and 3^{rd} reference values. The analog signal VIN is compared with the 3 reference levels REF. The three comparators 304 generate three digital signals comp_1, comp 2, and comp_3 characteristic of the comparison (“out[1]=comp_1”,“out[2]=comp_2” and “out[3]=comp_3”).

If the first comparator still has a low output voltage (“comp_1==0”), the controller step 366, is configured to generate the CTRL control signal instructing the generator 302 to remain at the minimum level.

In this algorithm, if the first comparator has a low output voltage, the controller 306 is configured to decrement the counter COUNT and to generate the control signal CTRL instructing the generator 302 to switch to the lower level. If the third comparator has a high output voltage, the controller 306 is configured to increment the counter COUNT and to generate the control signal CTRL instructing the generator 302 to switch to the higher level. If the first comparator has a high output voltage, and the third comparator has a low output voltage, then the current level is considered suitable, and the controller 306, in a step 370, is configured to leave the value of counter COUNT unchanged and to generate the control signal CTRL instructing the generator 302 to remain at the current level and generate the same reference levels REF.

An example of the evolution of reference levels according to this algorithm is described in Table 1 below for device 300.

TABLE 1

| | T1 | T2 | T3 | T4 | T5 | T6 |
|---|---|---|---|---|---|---|
| Vx₅ | | | 0 | 0 | 0 | |
| Vx₄ | 0 | 1 | 1 | 0 | 0 | 0 |
| Vx₃ | 1 | 1 | 1 | 1 | 0 | 0 |
| Vx₂ | 1 | 1 | | | | 1 |

The first column illustrates examples of reference voltage values (Vx₂, Vx₃, Vx₄, Vx₅), and the next six columns illustrate the status of the output signal REF of the three comparators for six periods (T1, T2, T3, T4, T5, T6) of the clock signal CLK.

In the example shown in Table 1, at the start of period T1, generator 302 is at level 2 and reference levels Vx₂, Vx₃, and Vx₄ are transmitted by module 302 to the three comparators of module 303. The two comparators taking Vx₂ and Vx₃ as inputs output the digital signals COMP having a high voltage (“1”) meaning that the analog signal VIN has a voltage higher than the voltages Vx₂ and Vx₃, and the comparator taking Vx₄ as input outputs the digital signal having a low voltage (“0”) meaning that the analog signal VIN has a voltage lower than the voltage Vx₄. This is the case where the first comparator has a high output voltage, and the third comparator has a low output voltage. The controller 306 is therefore configured to generate the control signal CTRL, instructing the generator 302 to remain at the current level and generate the same reference levels REF.

At the start of period T2, generator 302 is at level 2, and reference levels Vx₂, Vx₃, and Vx₄ are transmitted by module 302 to the three comparators of module 303. The three comparators output digital signals COMP with a high voltage, meaning that analog signal VIN has a voltage higher than voltages Vx₂, Vx₃, and Vx₄. This is the case where the third comparator has a high output voltage. The controller 306 is therefore configured to generate the control signal CTRL, instructing the generator 302 to switch to the higher level, to level 3.

At the start of period T3, generator 302 is at level 3, and reference levels Vx₃, Vx₄, and Vx₅ are transmitted by module 302 to the three comparators of module 303. The two comparators taking Vx₃ and Vx₄ as inputs output the digital signal having a high voltage meaning that the analog signal VIN has a voltage higher than the voltages Vx₃ and Vx₄, and the comparator taking Vx₅ as input outputs the digital signal having a low voltage meaning that the analog signal VIN has a voltage lower than the voltage Vx₅. This is the case where the first comparator has a high output voltage, and the third comparator has a low output voltage. The controller 306 is therefore configured to generate the control signal CTRL, instructing the generator 302 to remain at the current level and generate the same reference levels REF.

At the start of period T4, generator 302 is at level 3, and reference levels Vx₃, Vx₄, and Vx₅ are transmitted by module 302 to the three comparators of module 303. The comparator taking Vx₃ as input transmits as output the digital signal having a high voltage meaning that the analog signal VIN has a voltage higher than the voltage Vx₃. The two comparators taking Vx₄ and Vx₅ as inputs output the digital signal with a low voltage, meaning that the analog signal VIN has a voltage lower than the voltages Vx₄ and Vx₅. This is the case where the first comparator has a high output voltage, and the third comparator has a low output voltage. The controller 306 is therefore configured to generate the control signal CTRL, instructing the generator 302 to remain at the current level and generate the same reference levels REF.

At the start of period T5, generator 302 is at level 3, and reference levels Vx₃, Vx₄, and Vx₅ are transmitted by module 302 to the three comparators of module 303. The three comparators output the digital signal with a low voltage, meaning that the analog signal VIN has a lower voltage than the voltages Vx₃, Vx₄, and Vx₅. This is the case where the first comparator has a low output voltage. The controller 306 is therefore configured to generate the control signal CTRL instructing to the generator 302 to switch to the lower level, to level 2.

At the start of period T6, generator 302 is at level 2, and reference levels Vx₂, Vx₃, and Vx₄ are transmitted by module 302 to the three comparators of module 303. The comparator taking Vx₂ as input transmits as output the digital signal having a high voltage meaning that the analog signal VIN has a voltage higher than the voltage Vx₂. The two comparators taking Vx₃ and Vx₄ as inputs output the digital signal with a low voltage meaning that the analog signal VIN has a voltage lower than the voltages Vx₃ and Vx₄. This is the case where the first comparator has a high output voltage, and the third comparator has a low output voltage. The controller 306 is therefore configured to generate the control signal CTRL instructing the generator 302 to remain at the current level and generate the same reference levels REF.

In the example shown in Table 1, the device 300 seeks to frame the voltage value of the signal VIN, and the reference levels REF are chosen to track variations in the signal VIN over time.

Table 1 illustrates an example of programming the controller 306, and other programming are possible for the same analog signal VIN and the same number of comparators. For example, the reference levels can be shifted by two levels within a period.

A different number of comparators can be used. The number is chosen, as a function of the anticipated variations in the analog signal VIN. The slower the variations in the analog signal VIN are likely to be, for example at most one level per period of the clock signal CLK, the fewer the number of comparators required.

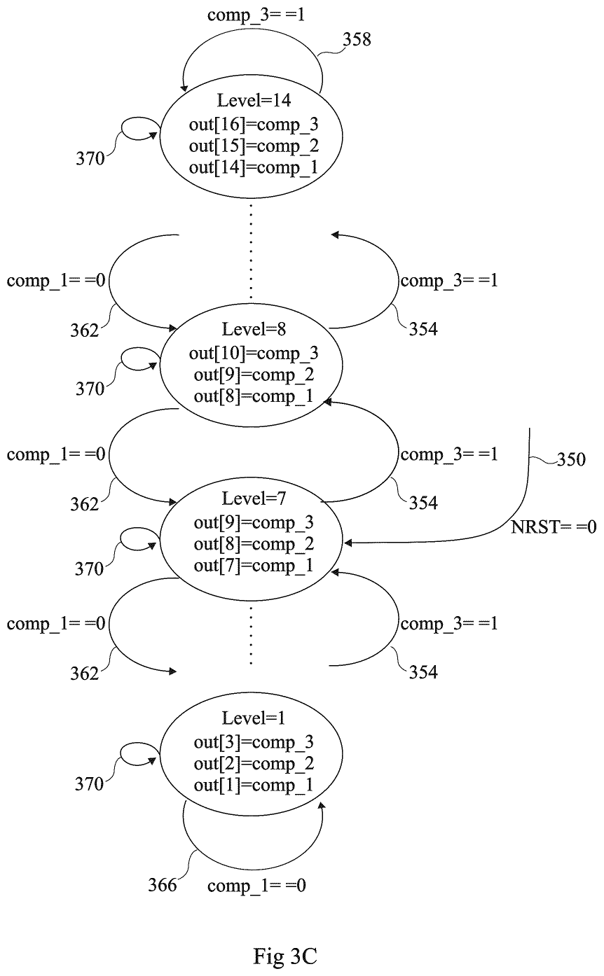

FIG. 4 graphically illustrates an example of the evolution in the voltage (“V”) of signals CLK, comp_m, NUM, CTRL, REF present in the device 300 shown in FIG. 3A over time (“t [%]”), expressed as a percentage of one period of the clock signal CLK.

The voltage of the clock signal CLK, the voltage comp m of one of the M digital output signals COMP of a comparator 304 of module 303, the voltage of the digital output signal NUM, the voltage of the control signal CTRL transmitted by controller 306, and the voltage of one of the M reference levels REF are illustrated in FIG. 4.

At start of a period of clock signal CLK, at time 0%, e.g. at a rising edge of the clock signal CLK, the comparators 304 of module 303 are activated, and compare the analog signal VIN with the reference levels REF established in the previous period. Each of the M signals COMP converges to a value representative of the comparison, for example over the 0-10% period. The circuit NUM GEN of the controller 306 takes the signals COMP as input, and adjusts the voltage level of the digital output signal NUM, for example at time 10%. The circuit CTRL GEN of the controller 306 receives the digital signal NUM, and is configured to generate the control signal CTRL, for example at time 20%, used by the module 302 to generate reference levels REF for the next period. For example, over the period from 20 to 100%, the reference levels REF are generated by module 302 and converge.

In the example shown in FIG. 4, the voltage level of the illustrated signal comp_m decreases, over the period from 0 to 10%, reflecting a decrease in the voltage of the analog signal VIN, not illustrated in FIG. 4. In response, the voltage level of the digital output signal NUM decreases, at time 10%, and the voltage level of the signal CTRL, for example, decreases, at time 20%, the generator 302 is then configured to switch to the lower level to continue monitoring the evolution of the analog signal VIN. The voltage level of the illustrated signal REF decreases, over the period from 20% to 100%, corresponding to the decrease in the generated reference levels.

In another embodiment, the period starts on a falling edge of the clock signal CLK.

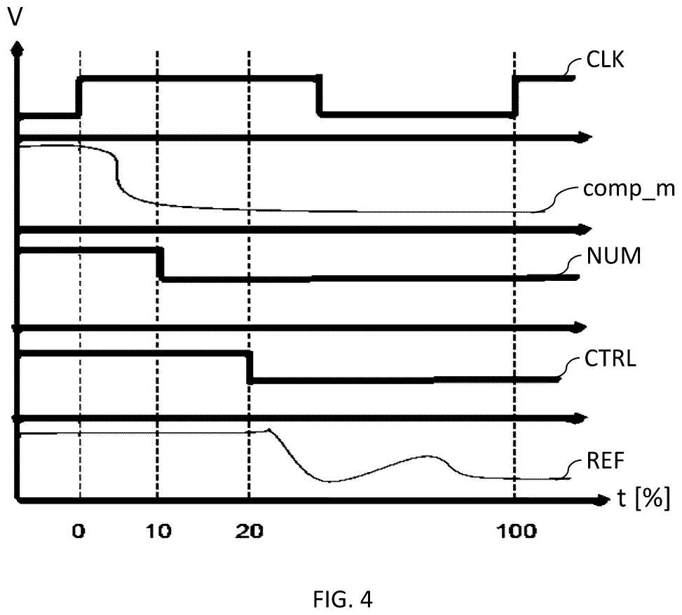

FIG. 5 illustrates, in flowchart form, a method for converting the analog signal VIN shown in FIG. 3A, according to one embodiment. The method steps are carried out, for example, by the reference level generator 302, comparators 304, and controller 306 shown in FIG. 3A.

In a step 502 (“REFERENCE GENERATION”), reference levels REF are generated by the reference level generator 302. When the device is initialized, the reference levels correspond, for example, to the M median levels of the N possible levels.

In a step 504 (“COMPARISON”) following step 502, the reference levels REF are compared with the analog signal VIN at a time indicated by the clock signal CLK, and the M digital signals COMP are generated by the module 303.

In a step 506 (“CONVERSION”) following step 504, the digital output signal NUM is generated, for example by the circuit NUM GEN of controller 306, at a time indicated by clock signal CLK and transmitted to output 320 of device 300.

In a step 508 (“COMMAND GENERATION”) following step 506, the control signal CTRL is generated, for example by the circuit CTRL GEN of controller 306, at a time indicated by clock signal CLK. The control signal CTRL is transmitted to module 302 for generating the new reference levels REF, and the method resumes at step 502.

FIG. 6 graphically illustrates an example of the evolution in the voltage (“V”) over time (“t”) of signals CLK, comp_1, NUM, CTRL present in the device 300 shown in FIG. 3A, in the case where the device 300 comprises only one comparator.

If the module 303 of the device 300 shown in FIG. 3A comprises at least two comparators, the voltage level of the analog signal VIN can be framed by two consecutive reference levels, as described in the example in Table 1.

On the contrary, if the module 303 comprises only a single comparator, during a given period of the clock signal CLK, it is possible to determine a minimum or maximum level for the voltage level of the analog signal VIN. Several periods should be used to frame and determine the level of the analog signal VIN.

An example of the signals corresponding to the application of a specific algorithm is shown in FIG. 6. The clock signal CLK oscillates periodically between two voltage values, and the times T1, . . . , T6 correspond to the consecutive rising edges. During the first period, between T1 and T2, the analog signal VIN is compared with a first reference value REF, and the digital signal comp_1 transmitted by the single comparator 304 switch to the high voltage, so the voltage of the analog signal VIN is higher than the first reference voltage. The voltage of the digital output signal NUM increases, indicating a rise in the estimated voltage level of VIN. The voltage of the control signal CTRL also increases, so that a higher reference level, corresponding to a second reference voltage, is used in the next period.

Between T2 and T3, the analog signal VIN is compared with the second reference value REF, and the digital signal voltage comp_1 remains at high voltage. The voltage of the analog signal VIN is therefore higher than the second reference voltage. The voltage of the digital output signal NUM increases, indicating a rise in the estimated voltage level of VIN. The voltage of the control signal CTRL also increases, so that a higher reference level, corresponding to a third reference voltage, is used in the next period.

Between T3 and T4, the voltage of the digital signal comp_1 switches to the low voltage, which means that the voltage of the analog signal VIN is lower than the third reference voltage. The voltage of the digital output signal NUM decreases, indicating a decrease in the estimated voltage level of VIN, and the voltage of the control signal CTRL also decreases, so that a lower reference level, e.g. corresponding to the second reference value, is used in the next period.

Between T4 and T5, the voltage of the digital signal comp 1 rises, so that the voltage level of the analog signal VIN is higher than the second reference voltage. The voltage of the digital output signal NUM increases to indicate a rise in the estimated voltage level of VIN, and the voltage of the control signal CTRL also increases so that a higher reference level, for example corresponding to the third reference value, is used in the next period.

Between T5 and T6, the voltage of the signal comp_1 decreases, which means that the voltage of the digital analog signal VIN is lower than the third reference voltage. The voltage of the digital output signal NUM decreases, indicating a decrease in the estimated voltage level of VIN, and the voltage of the control signal CTRL also decreases, so that a lower reference level, e.g. corresponding to the second reference value, is used in the next period.

In the example shown in FIG. 6, a high voltage at the output of the single comparator leads to an increase in the reference voltage for the next period, and a low voltage at the output of the single comparator leads to a decrease in the reference voltage for the next period. As there is only one comparator, it is not possible to simultaneously frame the analog signal VIN by two reference values. However, an oscillation between two adjacent reference values is observed, for example, if the analog signal VIN lies between these two values, as illustrated between T2 and T6 shown in FIG. 6. This is possible if the analog signal VIN changes more slowly than the clock signal CLK.

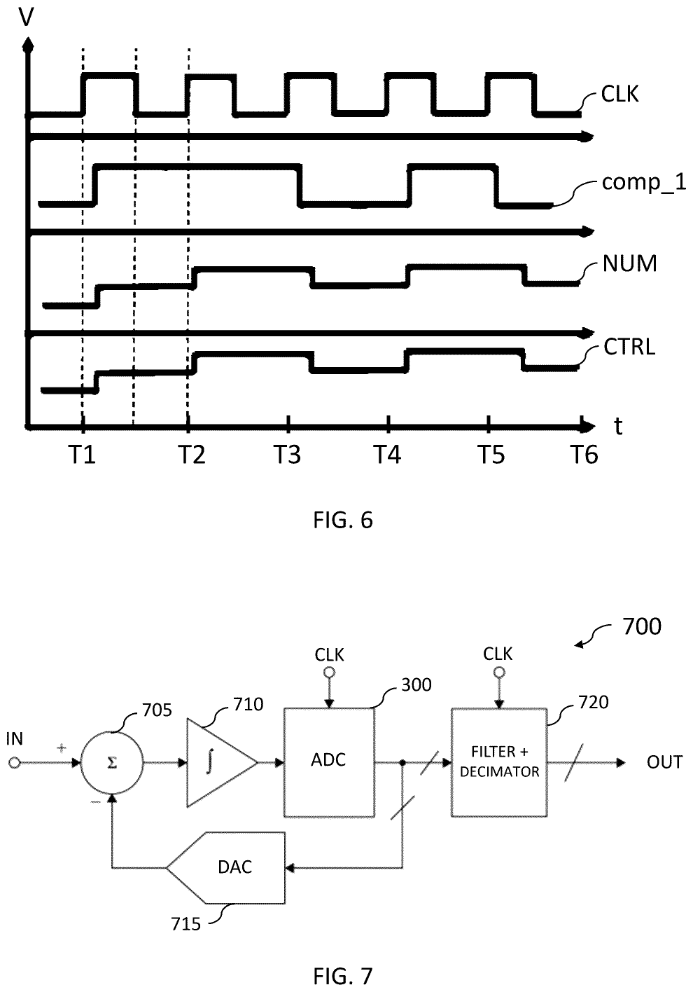

FIG. 7 illustrates a schematic diagram of a sigma-delta-type analog-to-digital converter 700 comprising, for example, the converter 300 shown in FIG. 3A.

The sigma-delta-type analog-to-digital converter 700 takes an analog input signal IN at one input, and is configured to generate a digital signal OUT. The converter 700 comprises, for example, a subtractor 705, an integrator 710 and an analog-to-digital converter (“ADC”), for example the converter 300 shown in FIG. 3A. The converter 700 also comprises, for example, in a feedback loop, a digital-to-analog converter 715 (“DAC”) taking as input the output signal of the ADC 300 and configured to generate a second analog signal. The subtractor 705 comprises a first input coupled to the input of the converter 700 and configured to receive the signal IN, and a second input configured to receive the second analog signal. The subtractor 705 is configured to generate a signal corresponding to the difference between the two input signals and transmit it to the integrator 710. The integrator 710 comprises one or more integration stages, and is configured to integrate the output signal from the subtractor 705 and generate the analog signal VIN. The signal VIN is transmitted to the analog-to-digital converter 300, which is configured to perform converting the analog signal VIN into the digital signal NUM. The analog-to-digital converter 300 also receives the clock signal CLK, and is configured to perform sampling the signal VIN, for example at a frequency higher than the Nyquist frequency to perform oversampling. The signal NUM is transmitted to the digital-to-analog converter 715. The signal NUM is also transmitted to a digital filter and decimator 720 (“FILTER +DECIMATOR”) configured to filter the signal NUM and generate the digital signal OUT.

Various embodiments and variants have been described. Those skilled in the art will understand that certain features of these embodiments can be combined and other variants will readily occur to those skilled in the art. In particular, a device comprises, for example, a plurality of converters 300 each configured to receive a subset of the samples of the analog signal VIN.

Finally, the practical implementation of the embodiments and variants described herein is within the capabilities of those skilled in the art based on the functional description provided hereinabove. In particular, voltage comparators are known in the art, and their practical implementation is therefore within the capabilities of those skilled in the art.

1. An analog-to-digital converter, comprising:
one or more comparators, each configured to compare an analog signal with a variable reference level specific to the comparator; and
a controller coupled to an output of the one or more comparators, and configured to generate a control signal indicating the reference level of each comparator as a function of an output signal of each of the one or more comparators, and configured to generate a digital output signal based on the output signal of each of the one or more comparators,
a voltage difference between two consecutive reference levels and a sampling frequency of the analog signal being chosen so that the variation in amplitude of the analog signal between two consecutive samples does not exceed twice said voltage difference.

2. The analog-to-digital converter according to claim 1, wherein the analog signal is oversampled.

3. The analog-to-digital converter according to claim 1, wherein the reference level of each comparator is selected from a plurality of discrete voltage levels.

4. The analog-to-digital converter according to claim 3, wherein the number of comparators is greater than or equal to two, and the reference levels of the comparators are selected to be consecutive levels from the plurality of discrete voltage levels.

5. The analog-to-digital converter according to claim 1, further comprising a reference level generator of the comparators, comprising a voltage divider formed by a plurality of series-connected resistors or diodes.

6. The analog-to-digital converter according to claim 5, wherein the reference level generator comprises a multiplexer configured to select the reference levels based on the control signal.

7. The analog-to-digital converter according to claim 1, further comprising at least one digital-to-analog converter coupled to an output of the controller and configured to convert the control signal into one or more reference voltage levels supplied to the one or more comparators or supplied to one or more voltage supply terminals of the reference level generator.

8. The analog-to-digital converter according to claim 1, wherein the controller is further configured to determine a number of comparators to be activated among the one or more comparators, as a function of a variation in amplitude of the digital output signal.

9. A Delta-Sigma analog-to-digital converter, comprising the analog-to-digital converter according to claim 1.

10. A method for analog-to-digital conversion, comprising:
comparing, by one or more comparators of an analog-to-digital converter, an analog signal with a variable reference level specific to the comparator;
selecting a voltage difference between two consecutive reference levels and a sampling frequency of the analog signal so that the variation in amplitude of the analog signal between two consecutive samples does not exceed twice said voltage difference;
generating a control signal, by a controller coupled to an output of the one or more comparators, indicating the reference level of each comparator as a function of an output signal of each of the one or more comparators; and
generating a digital output signal, by the controller, based on the output signal of each of the one or more comparators.

11. The method for analog-to-digital conversion according to claim 10, wherein the analog signal is oversampled.

12. The method for analog-to-digital conversion according to claim 10, further comprising selecting the reference level of each comparator from a plurality of discrete voltage levels.

13. The method for analog-to-digital conversion according to claim 12, wherein the number of comparators is greater than or equal to two, and the reference levels of the comparators are selected to be consecutive levels from the plurality of discrete voltage levels.

14. The method for analog-to-digital conversion according to claim 10, further comprising converting the control signal, by at least one digital-to-analog converter coupled to a controller output, into a voltage level supplied to a voltage divider, formed by a plurality of series-connected resistors or diodes, included in a reference level generator.

15. The method for analog-to-digital conversion according to claim 10, further comprising selecting reference levels based on the control signal, by a multiplexer coupled to an output of a reference level generator comprising a voltage divider formed by a plurality of series-connected resistors or diodes.
